(19) United States
(12) Patent Application Publication
(10) Pub. No.: US 2025/0052829 A1
(43) Pub. Date: Feb. 13, 2025

(54) SOC ESTIMATION DEVICE

(71) Applicant: TOYOTA JIDOSHA KABUSHIKI KAISHA, Toyota-shi (JP)

(72) Inventors: Yukinori MURAKAMI, Toyota-shi (JP); Yohei HOSOKAWA, Susono-shi (JP)

(73) Assignee: TOYOTA JIDOSHA KABUSHIKI KAISHA, Toyota-shi (JP)

(21) Appl. No.: 18/788,927

(22) Filed: Jul. 30, 2024

(30) Foreign Application Priority Data
Aug. 9, 2023 (JP) 2023-130052

(51) Int. Cl. G01R 31/388; G01R 31/378

(52) U.S. Cl. CPC G01R 31/388; G01R 31/378

(57) ABSTRACT

In SOC estimation device, the first estimation unit 36 estimates a reference value of SOC of the battery based on the voltage of the chargeable/dischargeable battery (auxiliary battery). The second estimation unit 38 estimates the estimated value of SOC of the battery based on the estimated reference value and the integrated value of the current of the battery. When the first estimation unit is not performing the process of estimating the reference value, the voltage of the battery is controlled within the first range. When the first estimation unit is executing the process of estimating the reference value, the voltage of the battery is controlled within the second range, and the second range includes a specific range outside the first range. The first estimation unit estimates the reference value based on the voltage of the battery when the value falls within the specific range.

### CROSS-REFERENCE TO RELATED APPLICATION

This application claims priority to Japanese Patent Application No. 2023-130052 filed on Aug. 9, 2023, incorporated herein by reference in its entirety.

### BACKGROUND

### 1. Technical Field

The present disclosure relates to a state of charge (SOC) estimation device.

### 2. Description of Related Art

A lithium ion battery is mounted on a vehicle or the like. In Japanese Unexamined Patent Application Publication No. 2022-139652 (JP 2022-139652 A), a stage capacity corresponding to a stage is measured until the timing when the stage is switched to another adjacent stage, or since the timing when the stage is switched. The document discloses a power storage device that estimates a full charge capacity of a lithium ion battery based on a reference capacity and the stage capacity.

### SUMMARY

A state of charge (SOC) of a battery can be estimated based on the measured voltage of the battery and the SOC-voltage characteristics of the battery acquired in advance. However, the SOC-voltage characteristics of lithium ion batteries and the like have a substantially flat area. The battery is occasionally controlled so as to be charged and discharged within this flat area. In this area, the SOC fluctuates relatively greatly with small variations in voltage, and therefore the SOC estimation accuracy may be reduced.

An object of the present disclosure is to provide an SOC estimation device capable of improving the SOC estimation accuracy.

In order to address the above issue, an aspect of the present disclosure provides a state of charge (SOC) estimation device including:
a first estimation unit that estimates a reference value for an SOC of a chargeable and dischargeable battery based on a voltage of the battery; and
a second estimation unit that estimates an estimated value of the SOC of the battery based on the estimated reference value and an integrated value of a current of the battery.
The voltage of the battery is controlled within a first range when the first estimation unit is not executing a process of estimating the reference value; and
the voltage of the battery is controlled within a second range when the first estimation unit is executing the process of estimating the reference value, the second range including a specific range outside the first range.
The first estimation unit estimates the reference value based on the voltage of the battery at a time when the voltage becomes a value within the specific range.

According to the present disclosure, it is possible to provide an SOC estimation device capable of improving the SOC estimation accuracy.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a diagram schematically illustrating a configuration of a solar charging system according to an embodiment;

FIG. 2 schematically illustrates an exemplary SOC-profile of the auxiliary battery of FIG. 1;

FIG. 3A is a diagram illustrating a state in which solar radiation is relatively large and power generated by a solar panel 10 is relatively large;

FIG. 3B is a diagram illustrating a state in which solar radiation is relatively low and power generated by a solar panel 10 is relatively low;

FIG. 3C is a diagram illustrating a state in which solar radiation is relatively small, power generated by a solar panel 10 is relatively small, and an auxiliary battery 14 is charged using power of a driving battery 20;

FIG. 4A is a diagram showing a state in which the solar panel 10 generates power;

FIG. 4B is a diagram illustrating a state in which solar radiation disappears and the solar panel 10 no longer generates electric power;

FIG. 5A is a diagram illustrating a state in which the bidirectional DC/DC converter 18 is stopped;

FIG. 5B is a diagram illustrating a state in which a charging operation of an auxiliary battery 14 is performed; and

FIG. 6 is a flow chart illustrating a process of estimating a reference value of SOC of the auxiliary battery.

### DETAILED DESCRIPTION OF EMBODIMENTS

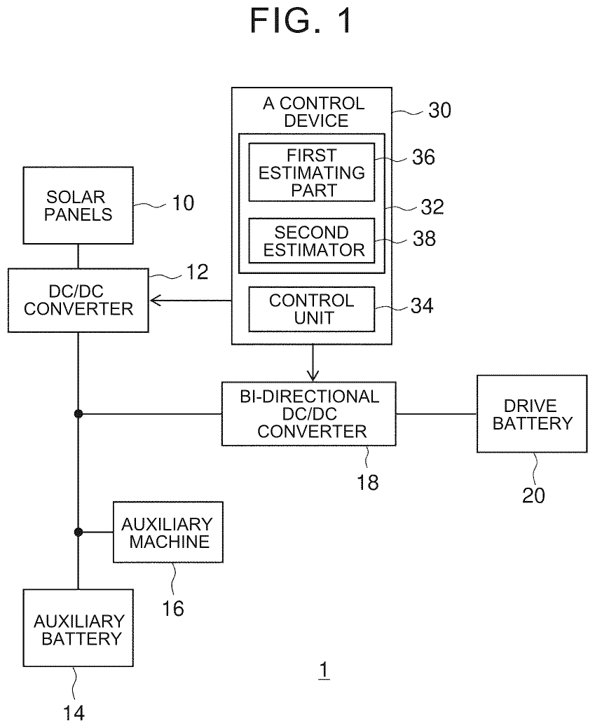

FIG. 1 schematically illustrates a configuration of a solar charging system 1 according to an embodiment. The solar charging system 1 is mounted on an electrified vehicle (not shown). Electrified vehicle may be, for example, a battery electric vehicle (BEV) using an electric motor as a power source, a hybrid electric vehicle (HEV)e, a plug-in hybrid electric vehicle (PHEV), or a fuel cell electric vehicle (FCEV). Electrified vehicle may be a vehicle driven by a driver or an autonomous vehicle.

The solar charging system 1 includes a solar panel 10, a DC/DC converter 12, an auxiliary battery 14, an auxiliary machine 16, a bi-directional DC/DC converter 18, a driving battery 20, and a control device 30.

The solar panel 10 is a solar cell module that is an assembly of solar cells that generate electric power based on irradiated solar light. The power generated by the solar panel 10 depends on the solar radiation intensity. The solar panel 10 is connected to an input terminal of DC/DC converter 12. The electric power generated by the solar panel 10 is outputted to DC/DC converter 12. The solar panel 10 is installed in, for example, a roof of a vehicle.

An output terminal of DC/DC converter 12 is connected to the auxiliary battery 14, the auxiliary machine 16, and the bidirectional DC/DC converter 18. DC/DC converter 12 can convert the generated power of the solar panel 10 into electric power and supply the electric power to the auxiliary battery 14, the auxiliary machine 16, and the bi-directional DC/DC converter 18. DC/DC converter 12 steps down or step up the output voltage of the solar panel 10 to a predetermined voltage under the control of the control device 30, and output the stepped down or boosted voltage to the auxiliary battery 14 or the like. DC/DC converter 12 provides maximum power point tracking (MPPT) control to maximize the power output of the solar panel 10.

The auxiliary battery 14 is, for example, a rechargeable secondary battery such as a lithium ion battery. The auxiliary battery 14 is a low-voltage battery having a voltage lower than that of the driving battery 20. The auxiliary battery 14 can be charged by electric power generated by the solar panel 10. The auxiliary battery 14 may be charged by the electric power of the driving battery 20. The auxiliary battery 14 is capable of supplying power to the auxiliary machine 16. The auxiliary battery 14 may charge the driving battery 20.

The auxiliary machine 16 is a load of an electronic device or the like provided in the vehicle. The auxiliary machine 16 may include, for example, a headlamp, a navigation device, an audio device, an air conditioner, an autonomous driving system, an advanced driving support system, and the like. The auxiliary machine 16 operates using electric power supplied from the auxiliary battery 14.

The bi-directional DC/DC converter 18 has a first terminal and a second terminal. The first terminal is connected to the output terminal of DC/DC converter 12 and the auxiliary battery 14. The second terminal is connected to the driving battery 20. The bidirectional DC/DC converter 18 operates in a first state in which the voltage at the first terminal is boosted and the voltage after the boosting is output from the second terminal, or in a second state in which the voltage at the second terminal is stepped down and the voltage after the boosting is output from the first terminal under the control of the control device 30.

The driving battery 20 is, for example, a rechargeable secondary battery such as a lithium ion battery. The driving battery 20 may also be referred to as a high voltage battery. The driving battery 20 can supply electric power to an electric motor that generates a driving force of the vehicle via an inverter (not shown) or the like. The driving battery 20 can be charged with electric power supplied from a charging station or the like outside the vehicle via an in-vehicle charging device (not shown).

The control device 30 controls DC/DC converter 12 and the bidirectional DC/DC converter 18 on the basis of an output voltage of the solar panel 10 detected by a voltage sensor and a current sensor (not shown), a voltage and a current of the auxiliary battery 14, a voltage of the driving battery 20, and the like. The control device 30 includes a SOC estimation unit 32 and a control unit 34.

The configuration of the control device 30 may be realized by hardware, a CPU of any computer, a memory, or another LSI, and may be realized by software, a program loaded into the memory, or the like. However, the functional blocks realized by the cooperation are illustrated here. Therefore, it is understood by those skilled in the art that these functional blocks can be implemented in various forms by hardware only, by software only, or by a combination of hardware and software.

SOC estimation unit 32 sequentially estimates the estimated value of SOC of the auxiliary battery 14 based on the voltage/current of the auxiliary battery 14, and sequentially supplies the estimated value of SOC to the control unit 34.

The control unit 34 controls the charging and discharging of the auxiliary battery 14 by controlling the bidirectional DC/DC converter 18 based on the received estimated SOC, the output voltage of the solar panel 10, the voltage and current of the auxiliary battery 14, and the voltage of the driving battery 20.

For example, the control unit 34 provides SOC estimation unit 32 with an estimation request of the reference value of SOC at regular intervals. The period of time can be determined as appropriate by experimentation or simulations so that the error of SOC estimate is within tolerance. For example, when a predetermined reference value estimation condition such as that the power switch or the ignition switch of the vehicle is turned on is satisfied, the control unit 34 may output an estimation request of the reference value of SOC.

SOC estimation unit 32 includes a first estimation unit 36 and a second estimation unit 38. The first estimation unit 36 starts a process of estimating a reference value when receiving an estimation request of a reference value of SOC from the control unit 34. The first estimation unit 36 estimates the reference value of SOC of the auxiliary battery 14 based on the voltage of the auxiliary battery 14 and SOC-voltage characteristic of the auxiliary battery 14. SOC-voltage-characteristics are stored in advance in a storage unit (not shown) of the control device 30. As will be described later, the first estimation unit 36 waits until the voltage of the auxiliary battery 14 changes to a value within a specified range after receiving an estimation request of the reference value of SOC, and then estimates the reference value. Upon completion of the estimation of the reference value once, the first estimation unit 36 notifies the control unit 34 of the end of the process of estimating the reference value. A period from when the estimation request of the reference value of SOC is received until when the end of the process of estimating the reference value is notified is defined as a period during which the process of estimating the reference value is being executed by the first estimation unit 36.

The length of the period during which the first estimation unit 36 is performing the process of estimating the reference value varies depending on SOC of the auxiliary battery 14 when the estimation request of the reference value of SOC is made, the operation status of the solar charging system 1, the power generation amount of the solar panel 10, and the like.

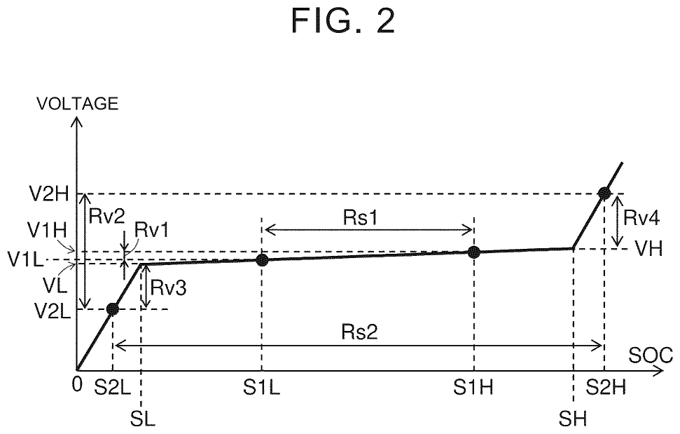

FIG. 2 schematically illustrates an exemplary SOC-profile of the auxiliary battery 14 of FIG. 1. The higher SOC, the higher the voltage.

In SOC-voltage property, the change amount of the voltage per unit change amount of SOC is equal to or less than a predetermined value in a range in which SOC is equal to or greater than the first value SL and equal to or less than the second value SH, that is, in a range in which the voltage is equal to or greater than the first value VL and equal to or less than the second value VH. This range is a region where SOC-voltage-characteristics are generally flat, and may also be referred to as a plateau region.

On the other hand, in SOC-voltage property, the change amount of the voltage per unit change amount of SOC is greater than a predetermined value in a range in which SOC is 0 or more and less than the first value SL, and in a range in which SOC is greater than the second value SH, that is, in a range in which the voltage is less than the first value VL, and in a range in which the voltage is greater than the second value VH. This range may also be referred to as a non-plateau region. As described above, the auxiliary battery 14 is a secondary battery having a plateau region and a non-plateau region.

The first range Rs1 of SOC is in the plateau region and is in a range from the lower limit value S1L to the upper limit value S1H. The first range Rv1 is a range corresponding to the first range Rs1 of SOC, and is a range from the lower limit value V1L to the upper limit value V1H. Within the first range Rs1, that is, within the first range Rv1, the amount of change in the voltage per unit-change amount of SOC of the auxiliary battery 14 is equal to or less than a predetermined value.

The second range Rs2 of SOC extends over the plateau region and the non-plateau region, and is a range of not less than the lower limit value S2L and not more than the upper limit value S2H. The second range Rv2 of the voltage is a range corresponding to the second range Rs2 of the voltage, and is a range of not less than the lower limit value V2L and not more than the upper limit value V2H.

The lower limit value S2L of SOC is smaller than the lower limit value SlL and smaller than the first value SL. The upper limit value S2H is greater than the upper limit value S1H and greater than the second value SH. That is, the upper limit value S2H and the lower limit value S2L of the second range Rs2 of SOC are outside the first range Rs1.

The lower limit value V2L is smaller than the lower limit value V1L and smaller than the first value VL. The upper limit value V2H is greater than the upper limit value V1H and greater than the second value VH. That is, the upper limit value V2H and the lower limit value V2L of the second range Rv2 are outside the first range Rv1.

The first range Rs1, Rv1 is determined to be a range in which degradation of the auxiliary battery 14 is easily suppressed. The first range Rs1, Rv1 and the second range Rs2, Rv2 may be determined experimentally or simulated as appropriate.

The second range Rv2 includes a specific range Rv3 and a specific range Rv4 that are outside the first range Rv1. In the second range Rv2, a range less than the first value VL is defined as a specific range Rv3, and a range larger than the second value VH is defined as a specific range Rv4. That is, within the specified range Rv3, Rv4, the amount of change in the voltage per unit-change amount of SOC of the auxiliary battery 14 is larger than the predetermined value. The upper limit value of the specific range Rv3 may be less than the first value VL, and the lower limit value of the specific range Rv4 may be greater than the second value VH.

The upper limit value S2H, V2H of the second range Rs2, Rv2 may be larger than the second value SH, VH, and the lower limit value S2L, V2L may be within the first range Rs1, Rv1. In this instance, a particular range Rv4 exists, but no particular range Rv3 exists. Alternatively, the lower limit value S2L, V2L of the second range Rs2, Rv2 may be smaller than the first value SL, VL, and the upper limit value S2H, V2H may be within the first range Rs1, Rv1. In this instance, a particular range Rv3 exists, but no particular range Rv4 exists. In these cases, the second range Rs2, Rv2 may be wider than the first range Rs1, Rv1, may be narrower, or may be as wide as the first range Rv1, Rs1.

The control unit 34 controls the charging and discharging of the auxiliary battery 14 so that the estimated value of SOC of the auxiliary battery 14 falls within the first range Rs1 from when the end of the process of estimating the reference value is notified from the first estimation unit 36 until the estimation request of the reference value of the next SOC is outputted. The control unit 34 may control the charging and discharging of the auxiliary battery 14 so that the voltage of the auxiliary battery 14 falls within the first range Rv1. Alternatively, the control unit 34 may control the charging and discharging of the auxiliary battery 14 so that the voltage of the auxiliary battery 14 falls within the first range Rv1 and the estimated value of SOC falls within the first range Rs1. The voltage of the auxiliary battery 14 falling within the first range Rv1 of the voltage is equivalent to the estimated value of SOC falling within the first range Rs1 of SOC. That is, when the first estimation unit 36 is not performing the process of estimating the reference value, the voltage of the auxiliary battery 14 is controlled within the first range Rv1. Details of the charge/discharge control will be described later.

The control unit 34 controls charging and discharging of the auxiliary battery 14 such that the estimated value of SOC falls within the second range Rs2 after outputting the estimation request of the reference value of SOC until the completion of the process of estimating the reference value is notified from the first estimation unit 36. The control unit 34 may control the charging and discharging of the auxiliary battery 14 so that the voltage of the auxiliary battery 14 falls within the second range Rv2. Alternatively, the control unit 34 may control the charging and discharging of the auxiliary battery 14 so that the voltage of the auxiliary battery 14 falls within the second range Rv2 and the estimated value of SOC falls within the second range Rs2. The voltage of the auxiliary battery 14 falling within the second range Rv2 of the voltage is equivalent to the estimated value of SOC falling within the second range Rs2 of SOC. That is, when the first estimation unit 36 is performing the process of estimating the reference value, the voltage of the auxiliary battery 14 is controlled within the second range Rv2.

The first estimation unit 36 estimates the reference value of SOC based on the voltage of the auxiliary battery 14 when the value falls within the specified range Rv3 or within the specified range Rv4 of the second range Rv2 and SOC-voltage property of the auxiliary battery 14. As will be described later, the voltage of the auxiliary battery 14 varies between the lower limit value and the upper limit value of the second range Rv2 according to the operation status of the solar charging system 1, the power generation amount of the solar panel 10, and the like, and thus may vary within the specified range Rv3 or within the specified range Rv4. The first estimation unit 36 supplies the estimated reference value to the second estimation unit 38.

The second estimation unit 38 sequentially estimates the estimated value of SOC of the auxiliary battery 14 based on the reference value estimated by the first estimation unit 36 and the integrated value of the charging current or the discharging current of the auxiliary battery 14 from the time point at which the reference value is estimated. Known techniques can be used to estimate an estimate of SOC using the integrated value of the reference value and the current. When the reference value is newly estimated by the first estimation unit 36, the second estimation unit 38 updates the reference value used for estimating the estimated value of SOC to a new reference value, and resets the integrated value of the current to zero.

As compared with the first range Rv1, the amount of variation of SOC per unit-variation of the voltage is smaller within the specified range Rv3 or within the specified range Rv4, so that the estimation accuracy of the reference value of SOC can be improved. Therefore, it is possible to improve the accuracy of the estimated value of SOC derived from the reference value. As a result, it is possible to suppress an unintended overcharge and overdischarge of the auxiliary battery 14.

On the other hand, in the comparative example in which the voltage of the auxiliary battery 14 is controlled within the first range Rv1 even when the process of estimating the reference value of SOC is being performed, the variation amount of SOC per unit variation amount of the voltage is relatively large. Therefore, as compared with the embodiment, the estimation accuracy of the reference value of SOC tends to decrease in accordance with the error of the detected value of the voltage or the like, and the reference value of SOC may deviate relatively greatly from the actual SOC. When the error of the reference value of SOC is relatively large, the error of the estimated value of SOC also becomes relatively large, and the auxiliary battery 14 is charge-discharge controlled based on the estimated value, so that there is a possibility that unintended overcharge or overdischarge occurs.

Further, in the embodiment, the reference value of SOC is estimated at regular intervals, and the estimated value of SOC is estimated based on the current integrated value from the time point at which the reference value is estimated. Accordingly, it is possible to prevent the error of the integrated current value from becoming larger than a certain value due to the error of the detected current value. Therefore, it is possible to prevent the error of SOC estimate from becoming larger than a certain value.

In addition, since both the upper limit value S2H and the lower limit value S2L of the second range Rs2 of SOC are outside the first range Rs1, there are a specific range Rv4 on the higher side and a specific range Rv3 on the lower side. Thus, if there is a demand for estimation of the reference value of SOC during the charge of the auxiliary battery 14, the voltage of the auxiliary battery 14 is more likely to fall within the specific range Rv4 of the higher side in a shorter time than it falls within the specific range Rv3 of the lower side.

If there is a requirement to estimate the reference value of SOC when the auxiliary battery 14 is discharging without being charged, the voltage of the auxiliary battery 14 is more likely to fall within the specific range Rv3 of the lower side in a shorter time than it falls within the specific range Rv4 of the higher side. Therefore, one of the upper limit value S2H and the lower limit value S2L of the second range Rs2 is outside the first range Rs1, and the reference value is easily estimated in a shorter time regardless of the timing of the estimation request of the reference value of SOC as compared with the case where the specified range is one.

### Charge/Discharge Restriction

Incidentally, the control unit 34 may change the control range of the charging and discharging of the auxiliary battery 14 according to whether or not there is a predetermined charging and discharging restriction. For example, the control unit 34 may specify that there is a charge/discharge restriction when the temperature or the like of the auxiliary battery 14 satisfies the predetermined condition, and may specify that there is no charge/discharge restriction when the predetermined condition is not satisfied.

When there is a charge/discharge restriction, the control unit 34 controls the charge/discharge of the auxiliary battery 14 such that at least one of the voltage of the auxiliary battery 14 and the estimated value of SOC falls within a third range (not shown) that differs from the first range. That is, when there is a charge/discharge restriction, the voltage of the auxiliary battery 14 is controlled within the third range.

The third range is in the plateau region. The third range is predetermined in accordance with the content of the charge/discharge restriction. The third range may be wider than or narrower than the first range Rv1, Rs1, or may be the same width as the first range Rv1, Rs1. In order to prevent overcharge, the third range may be set to a range in which the first range Rv1, Rs1 is moved downward. In order to prevent over-discharge, the third range may be set to a range in which the first range Rv1, Rs1 is moved upward. Known techniques can be used for setting the charge/discharge restriction and the third range.

When there is no charge/discharge restriction, the control unit 34 controls the charging and discharging of the auxiliary battery 14 so that at least one of the voltage of the auxiliary battery 14 and the estimated value of SOC falls within the first range from when the end of the process of estimating the reference value is notified to when the estimation request of the reference value of the next SOC is outputted. That is, when there is no charge/discharge restriction and the first estimation unit 36 is not performing the process of estimating the reference value, the voltage of the auxiliary battery 14 is controlled within the first range Rv1.

When there is no charge/discharge restriction, the control unit 34 controls the charging and discharging of the auxiliary battery 14 such that at least one of the voltage of the auxiliary battery 14 and the estimated value of SOC falls within the second range until the completion of the process of estimating the reference value is notified from the first estimation unit 36 after outputting the estimation request of the reference value of SOC. That is, when there is no charge/discharge restriction and the first estimation unit 36 is performing the process of estimating the reference value, the voltage of the auxiliary battery 14 is controlled within the second range Rv2.

When there is no charge/discharge restriction, the first estimation unit 36 estimates the reference value based on the voltage of the auxiliary battery 14 when the value falls within the specified range Rv3 or within the specified range Rv4. When there is a charge/discharge restriction, the first estimation unit 36 estimates the reference value based on the voltage of the auxiliary battery 14 within the third range.

As described above, when there is a charge/discharge restriction, the charge/discharge control within the third area can be prioritized even while the first estimation unit 36 performs the process of estimating the reference value of SOC. When there is no charge/discharge restriction, the accuracy of estimating the reference value of SOC can be improved.

### Charge/Discharge Control

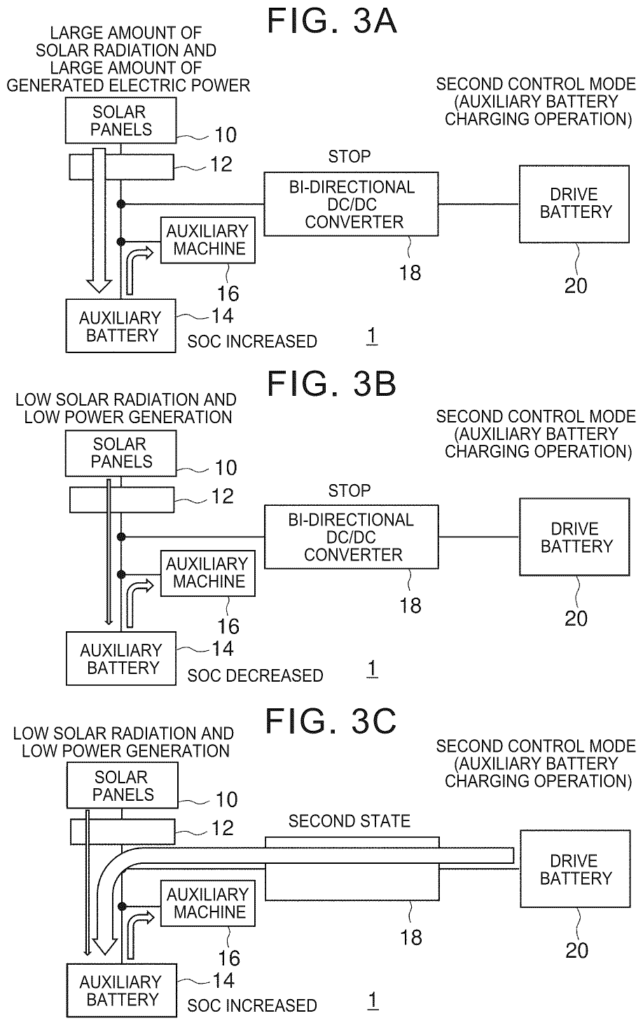

Next, the charging/discharging operation of the solar charging system 1 will be described referring to FIGS. 3A to 5B. In FIGS. 3A to 5B, the control device 30 is not illustrated.

The control unit 34 operates in the first control mode or the second control mode. The control unit 34 operates in the first control mode when the solar panel 10 is not solar-charged and the bidirectional DC/DC converter 18 is not operating in the first state. The control unit 34 operates in the second control mode when the solar panel 10 is solar-charging or when the bi-directional DC/DC converter 18 is operating in the first state. The solar charging corresponds to the power generation of the solar panel 10.

In the first control mode, the control unit 34 controls the bidirectional DC/DC converter 18 to be in the second state or the stopped state so that the estimated SOC of the auxiliary battery 14 falls within the control range. The control range is the first range Rs1, the second range Rs2, or the third range, and is selected as described above. In the second control mode, the control unit 34 controls the bidirectional DC/DC converter 18 to be in the first state, the second state, or the stopped state so that the estimated value of SOC of the auxiliary battery 14 is within the control range.

### Second Control Mode

FIGS. 3A to 3C are diagrams for explaining the charging operation of the auxiliary battery 14 in the second control mode.

FIG. 3A shows a situation in which solar radiation is relatively large and the generated electric power of the solar panel 10 is relatively large. The bidirectional DC/DC converter 18 is controlled to be stopped. In FIG. 3A, it is assumed that the power generated by the solar panel 10 is larger than the power consumed by the auxiliary machine 16. Therefore, the auxiliary battery 14 is charged with the generated electric power, and SOC of the auxiliary battery 14 is increased. Since the auxiliary battery 14 can be charged using the energy of sunlight, convenience is high. In FIGS. 3A to 5B, an arrow indicates a power supply path, and a thickness of the arrow schematically indicates a magnitude of power.

If the condition changes from a situation where there is a relatively large amount of solar radiation to a situation where there is a relatively small amount of solar radiation, the condition shifts to the condition shown in FIG. 3B.

FIG. 3B shows a situation in which solar radiation is relatively small and the generated electric power of the solar panel 10 is relatively small. The bidirectional DC/DC converter 18 is controlled to be stopped. In FIG. 3B, it is assumed that the power generated by the solar panel 10 is less than the power consumed by the auxiliary machine 16. Therefore, SOC of the auxiliary battery 14 is reduced by the electric power consumed by the auxiliary machine 16. If the solar radiation recovers, it returns to the condition shown in FIG. 3A.

When the solar radiation does not recover and the estimated value of SOC of the auxiliary battery 14 reaches the lower limit value of the control range, the operation shifts to the operation shown in FIG. 3C. That is, when solar charging is in progress, when the estimated value of SOC of the auxiliary battery 14 reaches the lower limit value of the control range, the control unit 34 controls the bidirectional DC/DC converter 18 to the second status so as to charge the auxiliary battery 14. Specifically, when the bidirectional DC/DC converter 18 is stopped while the solar power is being charged and the estimated value of SOC of the auxiliary battery 14 reaches the lower limit value of the control range, the control unit 34 controls the bidirectional DC/DC converter 18 to the second state.

FIG. 3C shows a situation in which the solar radiation is relatively low, the generated power of the solar panel 10 is relatively small, and the auxiliary battery 14 is charged using the power of the driving battery 20 as well, following FIG. 3B. In the state in FIG. 3C, the bi-directional DC/DC converter 18 operates in a second state in which the power of the driving battery 20 is supplied to the auxiliary battery 14. Accordingly, the auxiliary battery 14 is charged by the electric power of the driving battery 20 and the electric power generated by the solar panel 10, and SOC of the auxiliary battery 14 is increased. Therefore, SOC of the auxiliary battery 14 can be increased even if the solar radiation is insufficient.

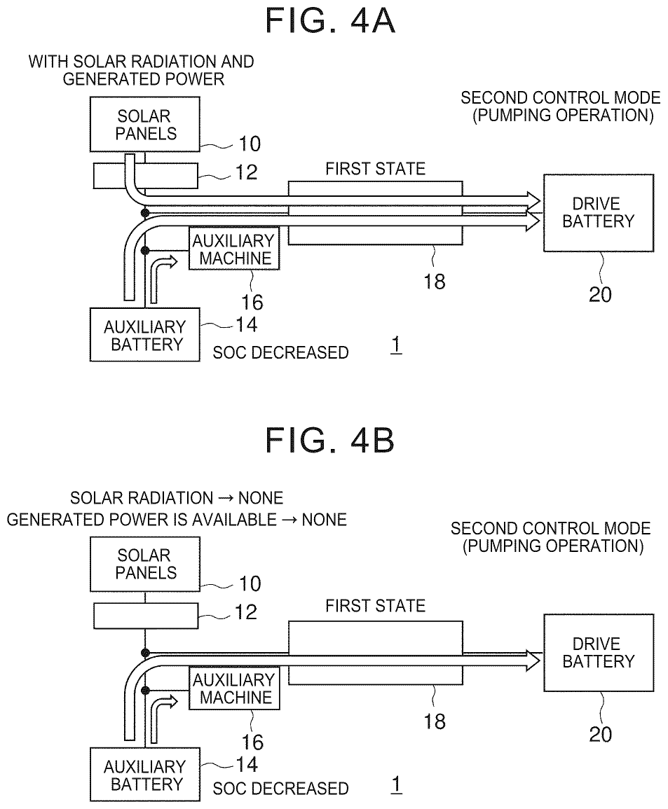

When the estimated value of SOC of the auxiliary battery 14 reaches the upper limit value of the control range due to the charge, the process shifts to the pumping operation in FIG. 4A.

On the other hand, when the solar radiation is relatively large in the state in FIG. 3A, and the estimated value of SOC of the auxiliary battery 14 reaches the upper limit value of the control range due to the electric power generated by the solar panel 10, the operation shifts to the pumping operation in FIG. 4A.

Specifically, when the solar battery is being charged, the control unit 34 controls the bidirectional DC/DC converter 18 to the first status so that the driving battery 20 is charged by the generated electric power of the solar panel 10 and the electric power of the auxiliary battery 14 when the estimated value of SOC of the auxiliary battery 14 reaches the upper limit value of the control range.

FIGS. 4A and 4B are diagrams for explaining a pumping operation in a second control mode. FIG. 4A shows that solar radiation is present and the solar panel 10 is generating electricity. In the state in FIG. 4A, the bi-directional DC/DC converter 18 operates in a first state in which the generated power of the solar panel 10 and the power of the auxiliary battery 14 are supplied to the driving battery 20. As a result, the driving battery 20 is charged with the electric power of the auxiliary battery 14 and the electric power generated by the solar panel 10. This operation is called a pumping operation. SOC of the driving battery 20 is increased, and SOC of the auxiliary battery 14 is decreased. Since the driving battery 20 can be charged with the electric power generated by the energy of the sunlight and the electric power of the auxiliary battery 14 including the generated electric power, it is highly convenient and economical.

When the estimated value of SOC of the auxiliary battery 14 reaches the lower limit value of the control range in the state shown in FIG. 4A, the operation proceeds to the FIGS. 3A and 3B. That is, when the solar battery is being charged, the control unit 34 controls the bidirectional DC/DC converter 18 to be stopped so as to charge the auxiliary battery 14 with the generated electric power of the solar panel 10 when the estimated value of SOC of the auxiliary battery 14 reaches the lower limit value of the control range. Specifically, the control unit 34 controls the bidirectional DC/DC converter 18 to be in the stopped state when the estimated value of SOC of the auxiliary battery 14 reaches the lower limit value of the control range when the solar charge is being performed and the bidirectional DC/DC converter 18 is operating in the first state. Accordingly, the auxiliary battery 14 can be charged again using the generated electric power of the solar panel 10. When the solar radiation is enough, the driving battery 20 can be repeatedly charged by the electric power generated by the energy of the sunlight by alternately repeating the conditions in FIGS. 3A and 4A.

FIG. 4B shows a state in which solar radiation disappears and the solar panel 10 no longer generates electric power in the state in FIG. 4A. When the bidirectional DC/DC converter 18 is operating in the first state in the second control mode, that is, when the pumping operation is being performed, the control unit 34 continues the second control mode even when the solar charge is ended. Therefore, the bidirectional DC/DC converter 18 that continues the operation in the first status continue to supply the electric power of the auxiliary battery 14 to the driving battery 20. Therefore, SOC of the auxiliary battery 14 is reduced. When the second control mode is continued even after the solar charge is completed, the control unit 34 moves to the first control mode when the estimated value of SOC of the auxiliary battery 14 reaches the lower limit value of the control range in the absence of the generated electric power of the solar panel 10.

This control allows the pumping operation to be continued even if the solar charging is completed during the pumping operation, and the power of the auxiliary battery 14 including the power generated by the solar panel 10 can be supplied to the driving battery 20 until the lower limit value of the control range is reached.

Further, even when the generated electric power of the solar panel 10 disappears during the charging operation of the auxiliary battery 14 of FIGS. 3A to 3C, the solar charging is terminated at that time. When the bidirectional DC/DC converter 18 is not operating in the first state in the second control mode, that is, when the pumping operation is not being performed, the control unit 34 moves to the first control mode when the solar charge ends.

### First Control Mode

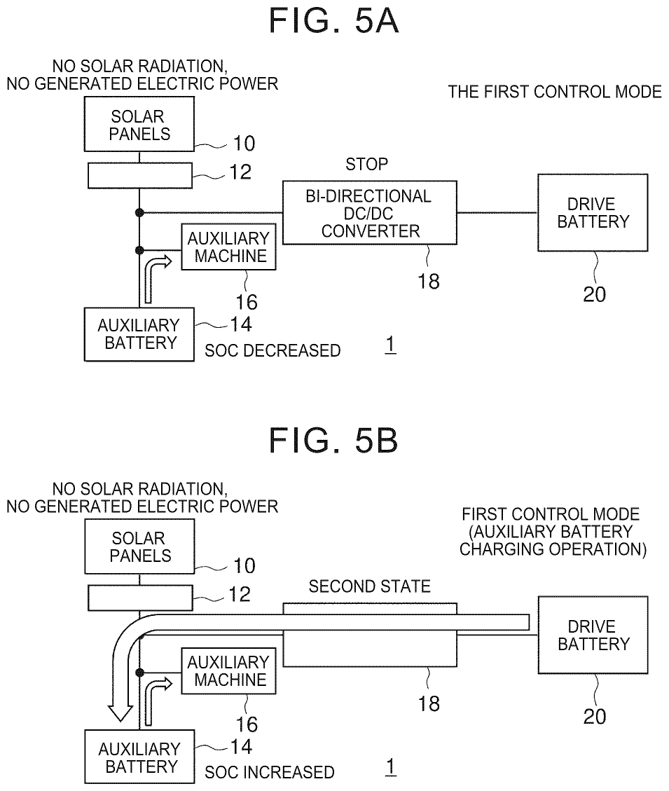

FIGS. 5A and 5B are diagrams illustrating an operation of a first control mode. FIG. 5A shows that the bi-directional DC/DC converter 18 is stopped. In the condition shown in FIG. 5A, since the solar panel 10 is not generating electricity, SOC of the auxiliary battery 14 is reduced due to the electricity consumed by the auxiliary machine 16.

When the estimated value of SOC of the auxiliary battery 14 reaches the lower limit value of the control range, the operation shifts to the operation shown in FIG. 5B. Specifically, in the first control mode, when the estimated value of SOC of the auxiliary battery 14 reaches the lower limit value of the control range, the control unit 34 controls the bidirectional DC/DC converter 18 to the second state.

FIG. 5B is a diagram illustrating a state in which a charging operation of an auxiliary battery 14 is performed. In the state in FIG. 5B, the bi-directional DC/DC converter 18 operates in a second state in which the power of the driving battery 20 is supplied to the auxiliary battery 14. As a result, the auxiliary battery 14 is charged with the electric power of the driving battery 20, and SOC of the auxiliary battery 14 is increased.

When the estimated value of SOC of the auxiliary battery 14 reaches the upper limit value of the control area due to the charge, the operation returns to the operation shown in FIG. 5A. Specifically, in the first control mode, when the estimated value of SOC of the auxiliary battery 14 reaches the upper limit value of the control range, the control unit 34 controls the bidirectional DC/DC converter 18 to be stopped.

In the first control mode, when the solar panel 10 starts power generation, solar charging is started. When the solar charging is started in the first control mode, the control unit 34 moves to the second control mode.

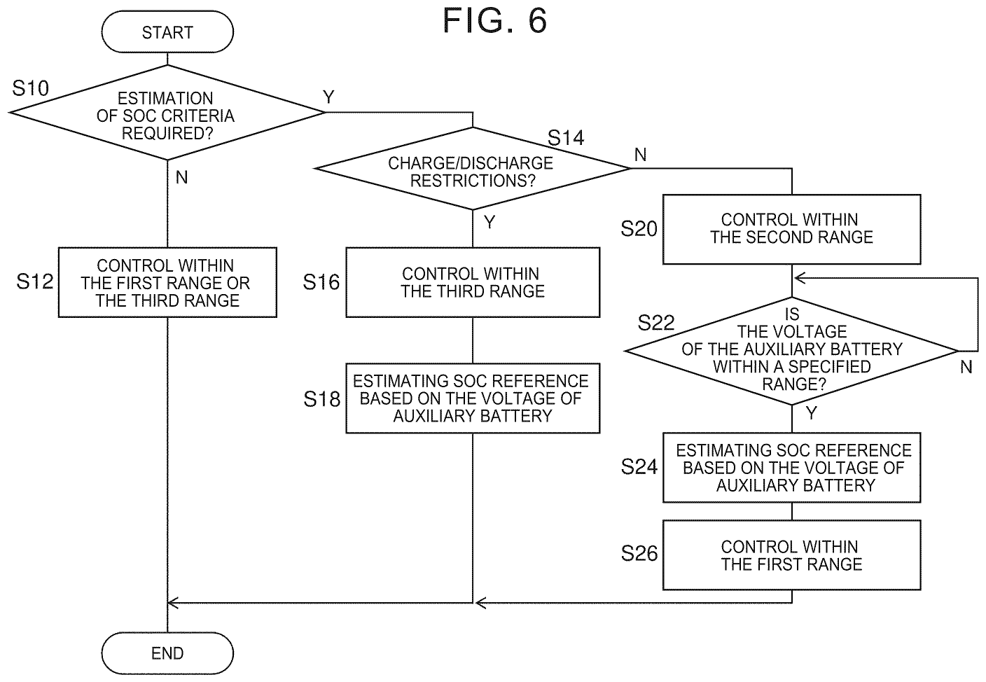

Next, an overall operation of the solar charging system 1 having the above-described configuration will be described. FIG. 6 is a flow chart illustrating a process of estimating a reference value of SOC of the auxiliary battery 14. The process of FIG. 6 is repeatedly executed.

If there is no requirement to estimate SOC reference (N in S10), the control unit 34 maintains the present control. That is, the control unit 34 controls SOC of the auxiliary battery 14 within the first range or the third range (S12), and ends the process.

When there is a requirement to estimate the reference value of SOC (Y in S10), if there is no charge/discharge restriction (N in S14), the control unit 34 controls SOC of the auxiliary battery 14 within the second range (S20). The first estimation unit 36 determines whether the voltage of the auxiliary battery 14 is within a specified range (S22). If the voltage of the auxiliary battery 14 is not within the specified range (N in S22), the process returns to S22. When the voltage of the auxiliary battery 14 is within the specified range (Y in S22), the first estimation unit 36 estimates the reference value of SOC based on the voltage of the auxiliary battery 14 (S24). Then, the control unit 34 controls SOC of the auxiliary battery 14 within the first area (S26), and ends the process.

If there is a charge/discharge restriction in S14 (Y in S14), the control unit 34 controls SOC of the auxiliary battery 14 within the third range (S16). The first estimation unit 36 estimates the reference value of SOC based on the voltage of the auxiliary battery 14 (S18), and ends the process.

In parallel with the process of FIG. 6, the second estimation unit 38 sequentially estimates the estimated value of SOC based on the integrated value of the reference value and the current. When the reference value of SOC is newly estimated by S18 or S24, the second estimation unit 38 estimates the estimated value of SOC based on the new reference value and the integrated value of the current from the time point at which the new reference value is estimated.

According to the embodiment, the reference value of SOC of the auxiliary battery 14 is estimated based on the voltage of the auxiliary battery 14 when the value falls within the specified range Rv3 or the specified range Rv4 of the second range Rv2. Therefore, it is possible to estimate the reference value of SOC outside the area where SOC-voltage-characteristic is substantially flat. Therefore, the estimation accuracy of SOC can be improved.

In addition, since the charging/discharging is controlled within the second range Rs2, Rv2 only during the process of estimating the reference value of SOC, degradation of the auxiliary battery 14 can be suppressed.

The present disclosure has been described with reference to the embodiments. Note that the embodiments are merely an example. It is to be understood by those skilled in the art that various modifications are possible by combining the components and the processing processes and that such modifications are also within the scope of the present disclosure.

For example, in the embodiment, an exemplary method of estimating SOC in the solar charging system 1 has been described. On the other hand, SOC of the auxiliary battery 14 may be estimated in the battery system in which the solar panel 10 and DC/DC converter 12 are excluded from the solar charging system 1. In this configuration, instead of the bidirectional DC/DC converter 18, a step-down converter capable of supplying the electric power of the driving battery 20 to the auxiliary battery 14 may be used. When the voltage or SOC of the auxiliary battery 14 reaches the lower limit of the control range by discharging to the auxiliary machine 16, the control unit 34 operates the step-down converter and charges the auxiliary battery 14 with the electric power of the driving battery 20. When the voltage or SOC of the auxiliary battery 14 reaches the upper limit of the control range, the control unit 34 stops the step-down converter. That is, the step-down converter is stopped except when the auxiliary battery 14 is charged. As in the embodiment, when the processing for estimating the reference value is not being executed by the first estimation unit 36, the voltage of the auxiliary battery 14 is controlled within the first range, and when the processing for estimating the reference value is being executed by the first estimation unit 36, the voltage of the auxiliary battery 14 is controlled within the second range. Also in this modification, the same effects as those of the embodiment can be obtained. Also in this modification, the control according to the presence or absence of the charge/discharge restriction of the embodiment may be executed.

What is claimed is:

1. A state of charge (SOC) estimation device comprising:
a first estimation unit that estimates a reference value for an SOC of a chargeable and dischargeable battery based on a voltage of the battery; and
a second estimation unit that estimates an estimated value of the SOC of the battery based on the estimated reference value and an integrated value of a current of the battery, wherein:
the voltage of the battery is controlled within a first range when the first estimation unit is not executing a process of estimating the reference value;
the voltage of the battery is controlled within a second range when the first estimation unit is executing the process of estimating the reference value, the second range including a specific range outside the first range; and
the first estimation unit estimates the reference value based on the voltage of the battery at a time when the voltage becomes a value within the specific range.

2. The SOC estimation device according to claim 1, wherein:
an amount of change in voltage per unit amount of change in SOC of the battery is equal to or less than a predetermined value when the voltage is within the first range; and
the amount of change in voltage per unit amount of change in SOC of the battery is more than the predetermined value when the voltage is within the specific range.

3. The SOC estimation device according to claim 1, wherein:
the voltage of the battery is controlled within the first range when a predetermined charge-discharge restriction is absent and the first estimation unit is not executing the process of estimating the reference value;
the voltage of the battery is controlled within the second range when the charge-discharge restriction is absent and the first estimation unit is executing the process of estimating the reference value;
the voltage of the battery is controlled within a third range that is different from the first range when the charge-discharge restriction is present; and
the first estimation unit is configured to
estimate the reference value based on the voltage of the battery at the time when the voltage becomes a value within the specific range when the charge-discharge restriction is absent, and
estimate the reference value based on the voltage of the battery within the third range when the charge-discharge restriction is present.

4. The SOC estimation device according to claim 1, wherein:
the battery is a lithium ion battery; and
the battery is charged with electric power generated by a solar panel.

5. The SOC estimation device according to claim 1, wherein the first estimation unit is configured to:
start a process in which the reference value is estimated upon receiving a request to estimate the reference value for the SOC; and
estimate the reference value and ends the process in which the reference value is estimated when the voltage of the battery becomes a value within the specific range.
